(19) United States
(12) Patent Application Publication
(10) Pub. No.: US 2026/0112582 A1
(43) Pub. Date: Apr. 23, 2026

(54) STRUCTURAL MEMBER

(71) Applicant: TOTO LTD., Fukuoka (JP)

(72) Inventors: Shun KATAOKA, Fukuoka (JP); Senri SAKAMOTO, Fukuoka (JP); Ryoto TAKIZAWA, Fukuoka (JP)

(73) Assignee: TOTO LTD., Fukuoka (JP)

(21) Appl. No.: 19/316,623

(22) Filed: Sep. 2, 2025

(30) Foreign Application Priority Data
Oct. 18, 2024 (JP) 2024-184123

(51) Int. Cl. H01J 37/32; C23C 24/04

(52) U.S. Cl. CPC H01J 37/32495; C23C 24/04

(57) ABSTRACT

A structural member 10 includes a substrate 100 and a passivation film 200 covering the surface 110 of the substrate 100. The passivation film 200 includes a crystal including lanthanum zirconium oxide as a main component and the crystal has a lattice constant of 10.830×10⁻¹⁰ m or more.

This application is based upon and claims the benefit of priority from Japanese Patent Application No. 2024-184123, filed on Oct. 18, 2024, the entire contents of which are incorporated herein by reference.

### FIELD

The present invention relates to a structural member.

### BACKGROUND

Resistance (Durability) against plasma is required for members constituting a semiconductor manufacturing apparatus, for example, members such as chamber inner walls and the like. Therefore, structural members having a protective film formed on the surface of a substrate (base material) have been commonly used as the above members as disclosed in Japanese Translation of PCT International Application Publication No. 2019-507962. Oxide ceramics, such as yttria, are often used as protective films.

### SUMMARY

The present inventors have been considering the use of lanthanum zirconium oxide as a material for protective films and further improvement in the resistance of protective film against plasma.

The present invention has been made in view of such problems and an object of the present invention is to provide a structural member having sufficient resistance against plasma.

To solve the above problem, the structural member of the present invention comprises a substrate and a protective film covering the surface of the substrate. The protective film comprises a crystal including lanthanum zirconium oxide as a main component, and the crystal has a lattice constant of 10.830×10⁻¹⁰ m or more.

The experiments conducted by the present inventors have demonstrated that there is a correlation between the lattice constant of protective film comprising a crystal including lanthanum zirconium oxide as a main component and the resistance of the protective film against plasma. It has also been confirmed that when crystals of the protective film are configured to have a lattice constant of 10.830×10⁻¹⁰ m or more, the resistance of the protective film against plasma can be sufficiently improved.

According to the present invention, a structural member with sufficient resistance against plasma can be provided.

### BRIEF DESCRIPTION OF THE DRAWINGS

FIG. 1 schematically illustrates a cross-section of the structural member;

FIG. 2 is a graph illustrating the relationship between the lattice constant of crystals of the protective film and the resistance of the protective film against plasma.

FIG. 3 is a graph illustrating the relationship between the lattice constant of crystals of the protective film and the resistance of the protective film against plasma;

FIG. 4 is a table listing film-forming conditions and the like when forming a protective film;

FIG. 5 shows micrographs illustrating the surface shape of the protective film; and

FIGS. 6A to 6C show micrographs illustrating the porosity of the protective film.

### DETAILED DESCRIPTION

Hereinafter the present embodiment will be described with reference to attached drawings. For clarity of description, identical reference numerals are used to denote the same elements in all figures, and redundant descriptions are omitted.

The structural member 10 of the present embodiment is configured as a member for a semiconductor manufacturing apparatus, such as a plasma etching apparatus. More specifically, the structural member 10 is a member used for the inner wall of a process chamber of semiconductor manufacturing apparatus. The use of the structural member 10 in the present embodiment is merely an example. The structural member 10 may be a member arranged within the process chamber of semiconductor manufacturing apparatus, such as a focus ring.

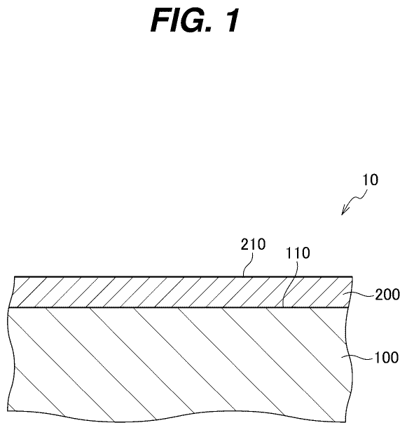

As shown in FIG. 1, the structural member 10 includes a substrate 100 and a protective film 200. In a plasma etching apparatus or the like, the surface 210 of the protective film 200 is exposed to the interior of the process chamber. The protective film 200 is formed to protect the surface 110 of the substrate 100 from plasma.

The substrate 100 is a member forming the primary portion of the structural member 10. In the present embodiment, the substrate 100 is a sintered ceramic body including high-purity aluminum oxide (Al₂O₃), but may be a different ceramic material or member other than a non-ceramic material (for example, a metal member). The surface 110 of the substrate 100 is flat in the present embodiment, but may be curved or tapered in portions.

The protective film 200 is formed to protect the substrate 100 from plasma as described above. The protective film 200 is formed to cover the entire surface 110 of the substrate 100. The protective film 200 is composed of a material including lanthanum zirconium oxide as a main component. Specifically, the protective film 200 comprises a crystal including lanthanum zirconium oxide as a main component, and the crystal forms the primary portion of the protective film 200.

Lanthanum zirconium oxide described above is, for example, La₂Zr₂O₇. The ratio among the number of lanthanum (La) atoms, the number of zirconium (Zr) atoms and the number of oxygen (O) atoms in the protective film 200 may be different from the ratio described above. The protective film 200 of the present embodiment is formed by using an aerosol deposition method, but may be formed by another film-forming method.

As used herein, the “main component” refers to the compound contained in the greatest amount in the target object (in this case, protective film 200). More specifically, the “main component” refers to the compound contained in the greatest amount in terms of volume ratio or mass ratio relative to other compounds in the object, as determined by quantitative or semi-quantitative analysis using X-ray diffraction (XRD) on the object.

The proportion of the main component (lanthanum zirconium oxide) in the protective film 200 of the present embodiment is more than 50% by volume or by mass. The proportion may be more than 70%, more than 90%, or may be 100%. The proportion of the crystal including lanthanum zirconium oxide as a main component in the protective film 200 may be more than 50%, more than 70%, more than 90%, or 100% by volume or by mass.

The thickness of the protective film 200 is appropriately adjusted depending on the duration for which resistance is required to be maintained and other factors. In the present embodiment, the protective film 200 has a thickness of 15 μm or less.

The present inventors have used lanthanum zirconium oxide as a material for the protective film 200 as in the present embodiment, and have been considering further improvement in the resistance of the material against plasma. As a result, it has been confirmed that there is a correlation between the lattice constant of the protective film 200 comprising a crystal including lanthanum zirconium oxide as a main component and the resistance of the protective film 200 against plasma.

In general, crystals of lanthanum zirconium oxide are cubic, and a=b=c and α=β=γ=90°. According to ICDD card reference code (PDF): 01-090-3310, the value of a (=b=c) in the lanthanum zirconium oxide crystal is typically 10.7460×10⁻¹⁰ m.

In the following description, “the lattice constant of the protective film 200” refers to the atomic distance (a, b, or c) in crystals in the protective film 200 including lanthanum zirconium oxide as a main component.

The lattice constant of the protective film 200 was measured using the following method. First, X-ray diffraction (XRD) was performed on the protective film 200 formed on the substrate 100 by out-of-plane measurement using a θ−2θ scan. From the obtained peak intensity distribution, the first, second, and third peaks, observed at around a diffraction angle 2θ=28.8°, 33.3°, and 47.8°, respectively, were extracted, and the lattice constant for each peak was individually calculated. Thereafter, the average of the respective lattice constants was calculated, with the resulting value taken as the lattice constant of the protective film 200. Other test methods and lattice constant calculations were performed using methods specified in JIS K 0131.

The peak attributable to the Miller index (hkl)=(222) is typically observed at around a diffraction angle 2θ=28.8°, but shifts in the range of 0.1 to 0.6° depending on the crystal structure of the protective film 200. Therefore, the first peak is likely to be identified as the peak attributable to the Miller index (hkl)=(222).

The peak attributable to the Miller index (hkl)=(400) is typically observed at around a diffraction angle 2θ=33.3°, but shifts in the range of 0.1 to 0.6° depending on the crystal structure of the protective film 200. Therefore, the second peak is likely to be identified as the peak attributable to the Miller index (hkl)=(400).

Likewise, the peak attributable to the Miller index (hkl)=(440) is typically observed at around a diffraction angle 2θ=47.8°, but shifts in the range of 0.1 to 0.6° depending on the crystal structure of the protective film 200. Therefore, the third peak is likely to be identified as the peak attributable to the Miller index (hkl)=(440).

The present inventors prepared multiple samples of the structural member 10 with varying film formation conditions for the protective film 200, and measured lattice constant and assessed resistance against plasma for each protective film 200. To evaluate the resistance of the protective film 200 against plasma, the surface 210 of each protective film 200 was exposed to a plasma environment using an inductively coupling plasma reactive ion etching (ICP-RIE) system (not shown). The following two sets of conditions were employed when exposing the surface 210 to the plasma environment.

Under the first condition, a 4-inch silicon wafer was held by an electrostatic chuck within the chamber of an inductively coupled plasma reactive ion etching system. A sample of the structural member 10, the subject of evaluation, was placed on the silicon wafer. Subsequently, the surface 210 of the protective film 200 was exposed to a plasma environment by generating plasma within the chamber. SF₆ was used as the process gas, and supplied to the chamber at a flow rate of 100 sccm. The pressure in the chamber was adjusted to 0.5 Pa. The time of exposure was 30 minutes. The power output was set to 1,500 W for the ICP coil and 750 W for the bias. The plasma exposure test for the surface 210 of the protective film 200, performed under the first conditions described above, is called the “First Standard Plasma Test” below. In the First Standard Plasma Test, by setting the bias output to 750 W as described above, the plasma is drawn toward the protective film 200, and used for the etching of the protective film 200.

Under the second condition, a 4-inch silicon wafer was held by an electrostatic chuck within the chamber of an inductively coupled plasma reactive ion etching system. A sample of the structural member 10, the subject of evaluation, was placed on the silicon wafer. Subsequently, the surface 210 of the protective film 200 was exposed to a plasma environment by generating plasma within the chamber. SF₆ was used as the process gas, and supplied to the chamber at a flow rate of 100 sccm. The pressure in the chamber was adjusted to 0.5 Pa. The time of exposure was 60 minutes. The power output was set to 1,500 W for the ICP coil, and the bias output was turned off (i.e., 0 W). The plasma exposure test for the surface 210 of the protective film 200, performed under the second conditions described above, is called the “Second Standard Plasma Test” below. In the Second Standard Plasma Test, by turning off the bias output as described above, the plasma is not drawn toward the protective film 200, and hardly used for the etching of the protective film 200. The surface 210 of the protective film 200 is simply exposed to non-directional plasma.

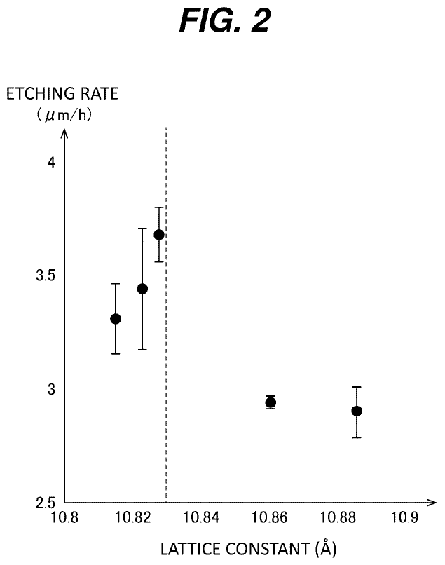

FIG. 2 shows the results of the First Standard Plasma Test described above conducted for each of the structural members 10. The horizontal axis of the graph in FIG. 2 represents the lattice constant of the protective film 200 samples, expressed in units of Å, namely 10⁻¹⁰ m.

The vertical axis of the graph in FIG. 2 represents the etching rate in the First Standard Plasma Test, specifically the depth to which the protective film 200 is etched per unit time, expressed in units of μm/h. The higher the resistance of the protective film 200 against plasma, the smaller the etching rate of the protective film 200. The etching rate may be used as an indicator of the resistance of the protective film 200 against plasma.

FIG. 2 shows the etching rates, with error bars, obtained from the First Standard Plasma Test for five samples of the structural member 10 with varying lattice constants of the protective film 200.

As FIG. 2 clearly shows, the larger the lattice constant of the protective film 200, the smaller the etching rate of the protective film 200. For the protective films 200 with a lattice constant of 10.830×10⁻¹⁰ m or more, i.e., to the right of the dotted line in FIG. 2, the etching rate is sufficiently low, and sufficient resistance against plasma was verified. If the lattice constant of the protective film 200 is 10.850×10⁻¹⁰ m or more, preferably 10.870×10⁻¹⁰ m or more, the etching rate is further reduced.

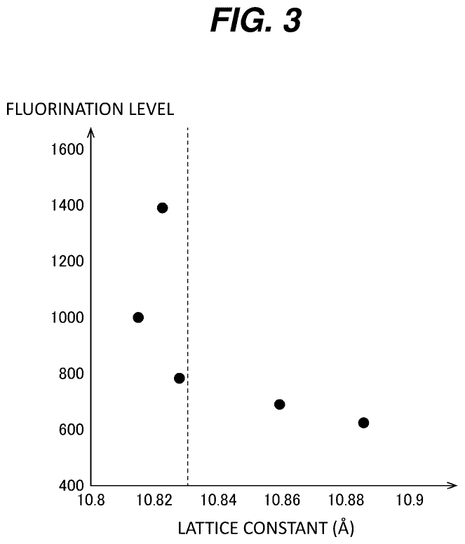

FIG. 3 shows the results of the Second Standard Plasma Test described above conducted for each of the structural members 10. The horizontal axis of the graph in FIG. 3 represents the lattice constant of the protective film 200 samples, expressed in units of Å, namely 10⁻¹⁰ m same as in FIG. 2. The samples prepared for the Second Standard Plasma Test were prepared by the same method as for the samples prepared for the First Standard Plasma Test. Therefore, the lattice constant value of each sample shown in FIG. 3 is the same as the lattice constant value of each sample shown in FIG. 2.

The vertical axis of the graph in FIG. 3 represents the fluorination level of the protective film 200 after the Second Standard Plasma Test. The “fluorination level” is an indicator of how deep fluorine atoms, which are part of plasma, penetrate into the interior of the protective film 200. Specific measurement methods of the fluorination level are as follows.

First, while sputtering the surface 210 of the protective film 200 after the Second Standard Plasma Test using argon, the amount of fluorine atoms present on the surface 210 was continuously measured by X-ray photoelectron spectroscopy (XPS). The measurement was performed for 145 seconds. During the measurement, the proportion of the measured argon concentration in the overall composition (in %) was calculated at each time point, and the integrated value of these proportions was defined as the “fluorination level” of the sample. The higher the resistance of the protective film 200 against plasma, the smaller the value of the fluorination level calculated as described above. Like the etching rate described above, the fluorination level may be used as an indicator of the resistance of the protective film 200 against plasma.

As FIG. 3 clearly shows, the larger the lattice constant value of the protective film 200, the smaller the fluorination level of the protective film 200. For the protective films 200 with a lattice constant of 10.830×10⁻¹⁰ m or more, i.e., to the right of the dotted line in FIG. 3, the fluorination level is sufficiently low, and sufficient resistance against plasma was verified. If the lattice constant of the protective film 200 is 10.850×10⁻¹⁰ m or more, preferably 10.870×10⁻¹⁰ m or more, the fluorine level is further reduced.

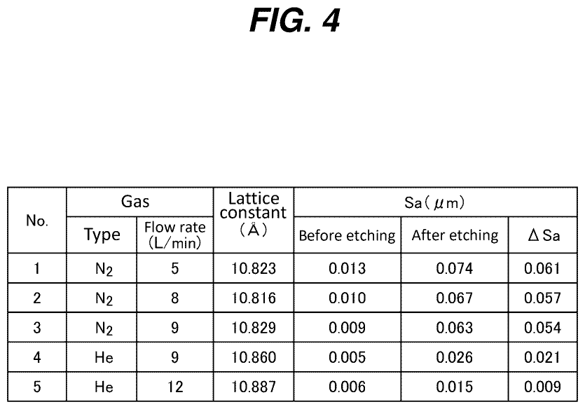

The method and other conditions for producing the samples used in the above measurement will be described with reference to FIG. 4. In FIG. 4, Sample No. 1 was prepared under conditions where the lattice constant of the protective film 200 was 10.823×10⁻¹⁰ m. Sample No. 2 was prepared under conditions where the lattice constant of the protective film 200 was 10.816×10⁻¹⁰ m; Sample No. 3 was prepared under conditions where the lattice constant of the protective film 200 was 10.829×10⁻¹⁰ m; Sample No. 4 was prepared under conditions where the lattice constant of the protective film 200 was 10.860×10⁻¹⁰ m; and Sample No. 5 was prepared under conditions where the lattice constant of the protective film 200 was 10.887×10⁻¹⁰ m.

All of the protective film 200 samples No. 1 to 5 were formed by using an aerosol deposition method. As is well known, in the aerosol deposition method, fine particles constituting the protective film 200 are dispersed in a gas to form an aerosol, which is then sprayed from a nozzle toward the surface 110 to collide with it. At the surface 110, fine particles are deformed or fractured upon collision, bonding and depositing progressively to form the protective film 200. FIG. 4 shows the type of the gas described above used in the film-forming of the samples and the flow rate in spraying the gas from the nozzle.

A La₂Zr₂O₇ powder was used as the “fine particles” described above. The powder had an average particle size of 2.3 μm and a median diameter of 2.1 μm.

As shown in FIG. 4, Samples No. 1 to 5 differ from one another in terms of the film-forming conditions for protective film 200 (specifically, gas type and flow rate), resulting in distinct lattice constants of the protective film 200.

Samples No. 1 to 5 were each prepared in pairs. The First Standard Plasma Test was conducted on one of each pair, yielding the results shown in FIG. 2. The Second Standard Plasma Test was conducted on the other, yielding the results shown in FIG. 3.

The present inventors measured the arithmetic mean height (Sa) of the surface 210 for Samples No. 1 to 5 before and after conducting the First Standard Plasma Test. In the “Before etching” column of the table in FIG. 4, the arithmetic mean height of the surface 210, measured prior to the First Standard Plasma Test, is shown in μm. In the “After etching” column, the arithmetic mean height of the surface 210, measured after the First Standard Plasma Test, is shown in μm. In the “ΔSa” column, the difference in the above two arithmetic mean heights is shown. Namely, the variation in the arithmetic mean height of the surface 210 after conducting the First Standard Plasma Test is shown in μm. The method specified in ISO25178 was used as the measurement method of the arithmetic mean height.

For Samples No. 1 to 3 with a lattice constant of the passivation film 200 of less than 10.830×10⁻¹⁰ m, the arithmetic mean height of the surface 210 of the passivation film 200 exceeds 0.05 μm after the First Standard Plasma Test. On the other hand, for Samples No. 4 and 5 with a lattice constant of the passivation film 200 of 10.830×10⁻¹⁰ m or more, the arithmetic mean height of the surface 210 of the passivation film 200 is less than 0.05 μm after the First Standard Plasma Test.

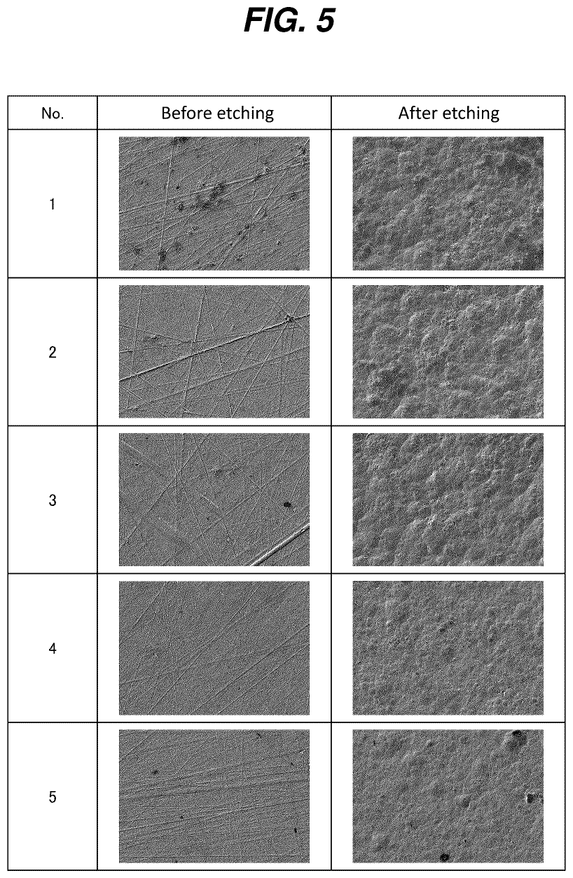

The present inventors observed the surface 210 of Samples No. 1 to 5 before and after conducting the First Standard Plasma Test using a scanning electron microscope (SEM). FIG. 5 shows images obtained from the observation. The images are what are called “secondary electron images,” which were obtained at an accelerated voltage of 3 kV. The magnification is 5000×. Images from the observation before the First Standard Plasma Test are shown in the “Before etching” column in FIG. 5. Images from the observation after the First Standard Plasma Test are shown in the “After etching” column in FIG. 5.

The present inventors also measured the porosity of the passivation film 200. The “porosity” as used herein refers to the proportion of the cross-sectional area occupied by pores, expressed as a percentage, in cross-sections of the passivation film 200 cut in a plane perpendicular to the surface 210.

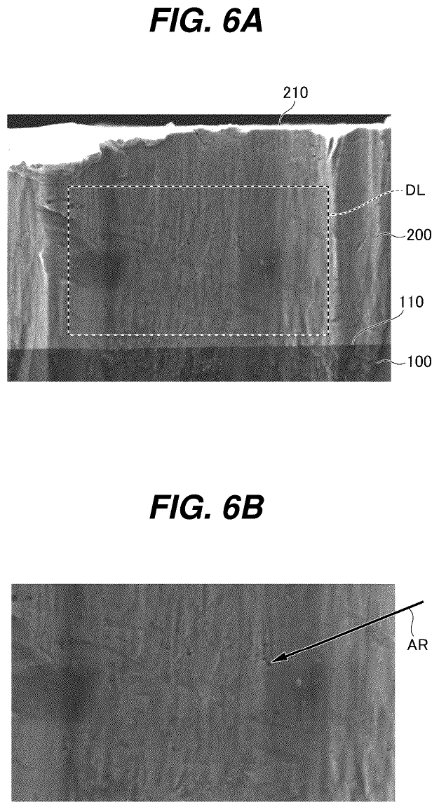

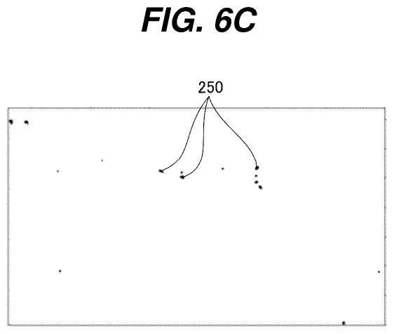

The method for measuring the porosity is as follows. First, the cross-sections described above are observed using a scanning electron microscope (SEM), and secondary electron images were obtained. The accelerated voltage was 3 kV and the magnification was 30,000×. FIG. 6A shows an example of images obtained by the procedure described above. The subject of the measurement is Sample No. 4 in the table in FIG. 4.

Next, by analyzing the images obtained as described above, the porosity of the passivation film 200 was calculated. Image analysis was performed using the OpenCV library in Python. The images were cropped to contain only the cross-section of the passivation film 200. Specifically, regions outside the dotted line DL in FIG. 6A were cropped.

FIG. 6B shows the image after the cropping described above. The entire image consists of the cross-section of the passivation film 200. In the image of FIG. 6B, dark spots, one of which is indicated by arrow AR, are the cross-sections of pores contained within the passivation film 200.

After cropping, the image of FIG. 6B was binarized to render the cross-sections of pores as black and other regions as white. The binarization was performed by applying the “Variable Threshold Binarization method” described in The Journal of the Institute of Image Electronics Engineers of Japan, 36(3), pp. 204-209, 2007. Subsequently, noise pixels were removed by dilation or other measures, yielding the binary image shown in FIG. 6C. In FIG. 6C, the black spots labeled 250 represent the cross-sections of pores contained within the passivation film 200.

The ratio of black pixels to total pixels in the image of FIG. 6C was determined as the porosity of the passivation film 200. In the example of FIG. 6C, the total number of pixels of the image was 947,200, with 981 black pixels. Therefore, the porosity was determined as approximately 0.10%. The present inventors have demonstrated that when the lattice constant of the passivation film 200 is 10.830×10⁻¹⁰ m or more and the porosity of the passivation film 200 is 0.15% or less, the resistance of the passivation film 200 against plasma can be further improved.

The present inventors have also demonstrated that by forming the passivation film 200 so that the average crystallite size is 50 nm or less, the resistance of the passivation film 200 against plasma can be further improved. The “average crystallite size” refers to the average diameter of the circles obtained by performing circular approximation on at least 15 crystallites present on the surface 210 of the passivation film 200. To calculate the average crystallite size of the passivation film 200, the surface 210 of the passivation film 200 is imaged using a Transmission Electron Microscope (TEM), and the average crystallite size can be calculated based on the acquired images. In this case, the magnification should preferably be 400,000× or higher.

By forming the passivation film 200 to have an average crystallite size of preferably 30 nm or less, and more preferably 15 nm or less, the resistance of the passivation film 200 can be further improved.

The present embodiment has been described with reference to examples. However, the present disclosure is not limited to these examples. Modifications made to the foregoing examples by those skilled in the art fall within the scope of the present disclosure, provided that they retain the characteristics of the present disclosure. The elements of the foregoing examples, including their configurations, conditions, shapes, and the like, are not limited to those illustrated and can be modified as appropriate. The elements of the foregoing examples can be variously combined, provided that no technical contradiction arises.

What is claimed is:

1. A structural member comprising:
a substrate, and
a passivation film covering a surface of the substrate,
wherein the passivation film comprises a crystal including lanthanum zirconium oxide as a main component, and
the crystal has a lattice constant of 10.830×10⁻¹⁰ m or more.

2. The structural member according to claim 1, wherein the passivation film is formed by using an aerosol deposition method.

3. The structural member according to claim 1, wherein the lanthanum zirconium oxide is La₂Zr₂O₇.

4. The structural member according to claim 1, wherein the crystal has a lattice constant of 10.850×10⁻¹⁰ m or more.

5. The structural member according to claim 1, wherein the crystal has a lattice constant of 10.870×10⁻¹⁰ m or more.

6. The structural member according to claim 1, wherein the passivation film has an average crystallite size of 50 nm or less.

7. The structural member according to claim 1, wherein the passivation film has a thickness of 15 μm or less.

8. The structural member according to claim 1, wherein an arithmetic mean height of a surface of the passivation film after conducting First Standard Plasma Test is smaller than 0.05 μm.

9. The structural member according to claim 1, wherein the passivation film has a porosity of 0.15% or less.

10. The structural member according to claim 1, which is configured as a member for a semiconductor manufacturing apparatus.
